(19) United States
(12) Patent Application Publication
(10) Pub. No.: US 2024/0354466 A1
(43) Pub. Date: Oct. 24, 2024

(54) APPARATUSES, COMPUTER-IMPLEMENTED METHODS, AND COMPUTER PROGRAM PRODUCTS FOR MODELING EXPECTED DEVICE ATTRIBUTES

(71) Applicant: Assurant, Inc., New York, NY (US)

(72) Inventors: Hinako JEFFERSON, Nashville, TN (US); Harrison HANKS, Nashville, TN (US)

(21) Appl. No.: 18/304,109

(22) Filed: Apr. 20, 2023

(51) Int. Cl. G06F 30/20

(52) U.S. Cl. CPC G06F 30/20

(57) ABSTRACT

Embodiments of the present disclosure provide for prediction of expected device attributes associated with a device. Embodiments utilize specially configured model(s) that perform determination of expected device attribute(s) based at least in part on device identifier(s) associated with the device. Such device identifier(s) may be identified via physical inspection, and/or not be retrievable by a human via mere inspection of the device itself. Embodiments de-obfuscate the device identifier(s), which on their own may not directly indicate or otherwise be immediately interpretable as corresponding to particular device attribute(s). Some embodiments receive at least one device identifier associated with a device, apply the at least one device identifier to an expected device attribute model that determines at least one expected device attribute associated with the device, where the model is a specially trained machine learning model, and outputs the at least one expected device attribute.

### TECHNOLOGICAL FIELD

Embodiments of the present disclosure generally relate to modeling predicted data value(s) for one or more data parameter(s) utilizing specially configured model(s), and specifically to generating expected device attributes associated with a particular device modeled based at least in part on at least one device identifier.

### BACKGROUND

Determining a device identity and/or one or more additional attributes associated with a device can be a cumbersome and manual process. In various circumstances, databases may be populated manually on a one-by-one, device-by-device basis and/or by hard-coding known relationships using information obtained from a manufacturer to create repositories of device data, which may be untenably time consuming and difficult to scale. In some instances, device attributes may be difficult to observe or discern based solely on external appearances.

Applicant has discovered problems with current implementations of determining expected device attributes, for example for validating a device identity and/or one or more additional attributes of a particular device. Through applied effort, ingenuity, and innovation, Applicant has solved many of these identified problems by developing embodied in the present disclosure, which are described in detail below.

### BRIEF SUMMARY

In general, embodiments of the present disclosure are provided for modeling expected device attributes, and/or using such modeled expected device attributes is provided. Other implementations for modeling expected device attributes will be, or will become, apparent to one with skill in the art upon examination of the following figures and detailed description. It is intended that all such additional implementations be included within this description be within the scope of the disclosure and be protected by the appended claims.

In accordance with a first aspect of the disclosure, a computer-implemented method for modeling expected device attributes is provided. In some example embodiments, the example computer-implemented method includes receiving at least one device identifier associated with a device. The example computer-implemented method further includes applying the at least one device identifier to an expected device attribute model that determines at least one expected device attribute associated with the device. The example computer-implemented method further includes outputting at least the at least one expected device attribute.

In some embodiments of the example computer-implemented method, the at least one expected device attribute comprises a device manufacturer, a device model, a device operating system, a device color, a device capacity, a device country of origin, or a combination of the device manufacturer, the device model, the device operating system, the device color, the device capacity, and the device country of origin.

In some embodiments of the example computer-implemented method, the at least one device identifier comprises device data that is unavailable via physically accessing an exterior of the device.

In some embodiments of the example computer-implemented method, the at least one device identifier comprises a device serial number, a device international manufacturer equipment identifier, a device SKU, a device part number, or a combination of the device serial number, the device international manufacturer equipment identifier, the device SKU, and the device part number.

In some embodiments of the example computer-implemented method, applying the at least one device identifier to the expected device attribute model includes determining the at least one expected device attribute comprising an expected physical condition of the device.

In some embodiments of the example computer-implemented method, outputting the at least at least one expected device attribute includes causing population of a user interface comprising an interface element associated with each device attribute of the at least one expected device attribute.

In some embodiments of the example computer-implemented method, outputting at least the at least one expected device attribute includes identifying image data corresponding to the at least one expected device attribute, and causing rendering of a user interface comprising at least the image data.

In some such embodiments of the example computer-implemented method, the example computer-implemented method further includes modifying the image data to include damage indication data associated with the device, and the image data comprises a representation of damage corresponding to the data indication data.

In some embodiments of the example computer-implemented method, outputting the at least at least one expected device attribute includes causing rendering of a user interface comprising a textual description of the at least one expected device attribute.

In some embodiments of the example computer-implemented method, the expected device attribute model is trained to determine a confidence value associated with each of the at least one expected device attribute.

In some embodiments of the example computer-implemented method, the expected device attribute model is trained to generate a confidence value associated with each of a plurality of candidate device attributes, and where the at least one expected device attribute is determined based at least in part on each confidence value satisfying a confidence threshold.

In some embodiments of the example computer-implemented method, the at least one expected device attribute comprises a plurality of candidate device attributes corresponding to a particular device attribute type.

In some embodiments of the example computer-implemented method, the example computer-implemented method further includes receiving feedback attribute data associated with at least a particular expected device attribute of the at least one expected device attribute, where the feedback attribute data indicates whether the particular expected device attribute accurately represented an actual device attribute of the device, and updating training of the expected device attribute model based at least in part on the feedback attribute data.

In some embodiments of the example computer-implemented method, the example computer-implemented method further includes receiving an image representation of the device, processing the image representation of the device utilizing at least one computer vision model that determines at least one actual device attribute associated with the device, generating comparison data representing results of a comparison of the actual device attribute with the at least one expected device attribute, and outputting the comparison data.

In some embodiments of the example computer-implemented method, receiving the at least one device identifier associated with the device includes receiving an image representation of the device, and processing the image representation of the device utilizing at least one computer vision model that extracts at least a first device identifier from the image representation.

In some embodiments of the example computer-implemented method, receiving the at least one device identifier associated with the device includes retrieving the at least one identifier via a software request executed on the device.

In some embodiments of the example computer-implemented method, the expected device attribute model comprises at least one specially-trained machine learning model.

In some embodiments of the example computer-implemented method, the example computer-implemented method further includes initiating a computer-implemented process based at least in part on the at least one expected device attribute.

In accordance with another aspect of the disclosure, an apparatus for modeling expected device attributes, and/or using such modeled expected device attributes is provided. In some example embodiments, an example apparatus includes at least one processor and at least one memory having computer-coded instructions stored thereon that, in execution with the at least one processor, causes the apparatus to perform any one of the example computer-implemented methods described herein. In other example embodiments, an example apparatus includes means for performing each step of any one of the example computer-implemented methods described herein.

In accordance with another aspect of the disclosure, a computer program product for modeling expected device attributes, and/or using such modeled expected device attributes is provided. In some example embodiments, an example computer program product includes at least one non-transitory computer-readable storage medium having computer program code stored thereon that, in execution with at least one processor, configures the computer program product for performing any one of the example computer-implemented methods described herein.

### BRIEF DESCRIPTION OF THE DRAWINGS

Having thus described the embodiments of the disclosure in general terms, reference now will be made to the accompanying drawings, which are not necessarily drawn to scale, and wherein:

FIG. 1 illustrates a block diagram of a system that may be specially configured within which embodiments of the present disclosure may operate;

FIG. 2 illustrates a block diagram of an example apparatus that may be specially configured in accordance with an example embodiment of the present disclosure;

FIG. 3 illustrates an example visualization of device identifiers associated with a particular device in accordance with at least some example embodiments of the present disclosure;

FIG. 4 illustrates an example visualization of training an expected device attribute model in accordance with at least some example embodiments of the present disclosure;

FIG. 5 illustrates an example visualization of modeling expected device attributes utilizing a trained model in accordance with at least some example embodiments of the present disclosure;

FIG. 6 illustrates a flowchart depicting example operations of a process for modeling expected device attributes in accordance with at least some example embodiments of the present disclosure;

FIG. 7 illustrates a flowchart depicting example operations of a process for outputting expected device attribute(s) via a populated user interface, for example as part of a process for modeling expected device attributes, in accordance with at least some example embodiments of the present disclosure;

FIG. 8 illustrates a flowchart depicting example operations of a process for outputting expected device attribute(s) via at least one image, for example as part of a process for modeling expected device attributes, in accordance with at least some example embodiments of the present disclosure;

FIG. 9 illustrates a flowchart depicting example operations of a process for outputting expected device attribute(s) via at least one textual description, for example as part of a process for modeling expected device attributes, in accordance with at least some example embodiments of the present disclosure;

FIG. 10 illustrates a flowchart depicting example operations of a process for determining whether actual device attribute(s) match expected device attribute(s), for example as part of a process for modeling expected device attributes, in accordance with at least some example embodiments of the present disclosure;

FIG. 11 illustrates a flowchart depicting example operations of a process for receiving device identifier(s) via image processing, for example as part of a process for modeling expected device attributes, in accordance with at least some example embodiments of the present disclosure; and

FIG. 12 illustrates a flowchart depicting example operations of a process for receiving device identifier(s) via software request(s), for example as part of a process for modeling expected device attributes, in accordance with at least some example embodiments of the present disclosure.

### DETAILED DESCRIPTION

Embodiments of the present disclosure now will be described more fully hereinafter with reference to the accompanying drawings, in which some, but not all, embodiments of the disclosure are shown. Indeed, embodiments of the disclosure may be embodied in many different forms and should not be construed as limited to the embodiments set forth herein, rather, these embodiments are provided so that this disclosure will satisfy applicable legal requirements. Like numbers refer to like elements throughout.

### Overview

In various contexts, confirmation of a device's identity and/or one or more additional attributes of a device is required or helpful. Often, confirmation of a device identity is attempted as a manual process—for example by having a user determine expected physical characteristics for a certain device, receive a device, and physically inspect the device to determine whether the actual characteristics of the device match the expected physical characteristics, which may include invasive and potentially damaging electronic and/or physical intrusion into the device. Expected physical characteristics may be determined from a central knowledge based, for example based on any details the computer has available to it that may be used to query the database for information associated with a particular device. In some instances, a user must gain electronic access to a device to determine information from onboard software of the device that is not outwardly observable, which access may be unavailable or additionally cumbersome. In some instances, portions of information may be unavailable from any source other than a manufacturer of the device.

Such a process suffers from various problems and technical inefficiencies. Inspection of a device in various circumstances may not yield sufficient data usable to identify all attributes of an expected device. For example, some device attributes (e.g., RAM amount) may not be visible from an exterior of the device and/or may be internal to the device (e.g., stamped on hardware of the device) such that inspection of such devices would require dismantling of the device, which may not be possible or at least is cumbersome, and such physical inspection fails to account for any software-maintained device identifiers that may be available only via operation of the device itself. In some contexts, even if all intended device identifiers are determinable from physical inspection, use of a database to maintain expected device identifiers provides a second point of inefficiency and failure. In some circumstances, such a database may become outdated, or otherwise may not include all expected characteristics for a particular device so as to result in an incomplete record. Further still, often device manufacturers and/or other related retailers do not publicize or otherwise make known any format between device identifiers and device attributes, such that generating a database with the relationship between device identifiers and attributes may be unduly complex or impossible to perform accurately.

Embodiments of the present disclosure provide for improved modeling of one or more expected device attributes associated with a device. Such embodiments may further provide for improved device handling and operation via identifying devices and/or attributes associated with unknown devices and directing one or more additional computing systems and/or device handling steps for repair, refurbishment, and/or further processing of the physical device(s) at large scales. The expected device attributes are modeled based at least in part on device identifier(s) associated with the device. Such device identifier(s) may include any one or more, or combination, of device identifier(s) determined in any of a myriad of ways, including visible identifier(s) identifiable via inspection of the device, and/or software-determinable identifier(s) associated with software, hardware, firmware, and/or other non-outward facing subcomponents of the device. In some embodiments, the expected device attributes are predicted utilizing a specially configured model, for example where the model is specially trained to identify patterns, indicators, or other trends between particular device identifier(s), or combination of device identifier(s), and particular device attribute(s). In this regard, such embodiments may model any expected device attribute(s) based at least in part on any identifiable device identifier(s), where the expected device attribute(s) may be utilized for any of a number of downstream technical and/or manual uses. In some embodiments, a computer vision system may be configured to capture the device identifier and/or one or more directly-observable attributes. In some embodiments, the detected device attribute(s) may be used to inform and control device repair, refurbishment, and/or diagnostics, including, but not limited to, authenticating and tracking a device within a provider facility. The model may further be used for fraud detection and secondary authentication by comparing expected device attribute(s) with reported device attribute(s). In some further embodiments, the various apparatuses herein may expose an API configured for calling to generate one or more expected device attribute(s) for a particular device.

Embodiments of the present disclosure provide a myriad of technical advantages. Embodiments of the present disclosure utilize one or more specially-trained model(s), for example an expected device attribute model, to identify any relationship between a device identifier, and/or combination of device identifiers, and one or more expected device attribute(s). Such relationship(s) include those relationship(s) that are not determinable by human-derived knowledge alone. Additionally, some embodiments perform software-executed process(es) that enable determination of additional device identifier(s), including entirely software-based device identifier(s) and/or hardware identifier(s) retrieved via software data signal(s). In this regard, some such embodiments utilize the device identifier(s) that are only software-determinable, and/or otherwise not determinable via mere human inspection alone, to enable more accurate and/or complex relationship(s) to be modeled. Additionally or alternatively still, utilizing specially-trained model(s), embodiments eliminate the need to maintain a robust and accurate database of device identifier(s) and corresponding expected physical attribute(s), Such embodiments conserve computing resources (e.g., processing resources, memory resources, and/or the like) that would otherwise be utilized in establishing and/or maintaining such a database. In some embodiments, the present disclosure includes models capable of externally capturing one or more device identifiers from an inert device (e.g., without turning the device on, electronically accessing the device, or requiring the device to be operable) and predicting a set of expected device attributes therefor.

### Definitions

The term “interface element” refers to any renderable data label or control. Non-limiting examples of an interface element include a text label, a button, a link, and a custom control.

The term “device” refers to one or more computer(s) embodied in any combination of hardware with software and/or firmware. Non-limiting examples of a device include a smartphone, tablet, personal computer, laptop, Internet-of-Things computer, smart assistant, and desktop computer. Some embodiments herein make reference to smartphones for example purposes, but the present disclosure is not necessarily limited solely to phones.

The term “device identifier” refers to data that uniquely identifies a particular device or subcomponent thereof. Non-limiting examples of a device identifier include a device serial number, a device international manufacturer equipment identifier (IMEI), a device SKU (e.g., a serial number of the device and/or a part of the device), and a device part number. In some embodiments, the device identifier may be externally observable without electronically accessing the device (e.g., an IMEI and/or serial number). In some embodiments, the model(s) disclosed herein may select, explicitly or inherently, one or more device identifiers based on external images of a device.

The term “device attribute” refers electronically managed data representing a physical characteristic of a device and/or a subcomponent thereof. Non-limiting examples of a device attribute include a device make, a device model, a device type, a device operating system, a device color, a device memory capacity (e.g., RAM amount), a device processor speed, and a device physical condition.

The term “actual device attribute” refers to a device attribute representing an actual characteristic of a particular device.

The term “expected device attribute” refers to a device attribute representing a predicted characteristic associated with a particular device corresponding to particular device identifier(s).

The term “expected device attribute model” refers to one or more algorithmic, statistical, and/or machine-learning model(s) that determines expected device attribute(s) based at least in part on particular device identifier(s).

The term “device capacity” refers to electronically managed data representing an amount of memory storage of a memory of a particular device (e.g., non-volatile memory). In some embodiments, device capacity is represented in bytes.

The term “physically accessing” refers to accessing physical component(s) of a device and/or software-driven functionality executed on the device.

The term “device part number” refers to electronically managed data embodying a numerical, alphanumeric, or alphabetical identifier that uniquely identifies a particular physical component of a device.

The term “physical condition” refers to electronically managed data that represents a visible characteristic of a device. Non-limiting examples of a physical condition include a color, a device model, a device shape, and a device damage.

The term “damage indication data” refers to electronically managed data that represents damage affecting a physical aspect of a device.

The term “device attribute type” refers to a particular category of characteristic associated with a device that has one or more possible values for the data attribute. Non-limiting examples of a device attribute type include a device color, a device make, a device model, a device country of origin, a device operating system, and a device hardware component.

The term “candidate device attribute” refers to a possible value for a particular device attribute type.

The term “confidence value” refers to electronically managed data representing a likelihood or determined probability, for a particular device attribute type, of a particular candidate device attribute representing an actual device attribute for a particular device as determined via an expected device attribute model.

The term “confidence threshold” refers to a minimum confidence value that represents a sufficient confidence level associated with an expected device attribute to indicate that the expected device attribute may represent the actual device attribute for a particular device based at least in part on an expected device attribute model.

The term “feedback attribute data” refers to electronically managed data representing an input by a user that indicates whether the particular expected device attribute accurately represents an actual device attribute of a particular device.

The term “computer vision model” refers to an algorithmic, statistical, and/or machine learning model that detect, extract, and/or otherwise derive particular data from image data. Non-limiting examples of a computer vision model includes a specially-trained neural network, a specially-trained machine-learning model, a specially-trained artificial intelligence, and/or at least one image process algorithm.

The term “comparison data” refers to electronically managed data that indicates whether a comparison condition is met or not met. Non-limiting examples of comparison data include a data value indicating two values match, a data value indicating two values do not match, a data value indicating that a first data value is greater than a second data value, and a data value indicating that a first data value is less than a second data value.

The term “computer-implemented process” refers to a software-driven action that is executed based at least in part on a device attribute.

The term “processing queue” refers to an order for initiating one or more computer-implemented process(es) associated with particular device(s) based at least in part on at least one device attribute.

### Example Systems and Apparatuses of the Disclosure

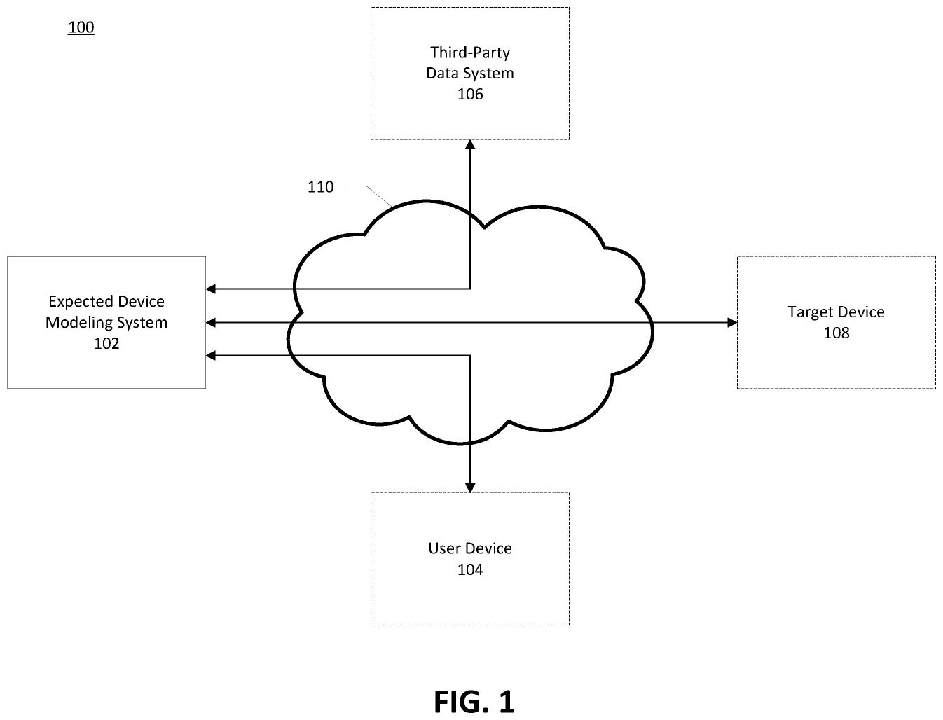

FIG. 1 illustrates a block diagram of a system that may be specially configured within which embodiments of the present disclosure may operate. Specifically, FIG. 1 illustrates an example system 100. The example system 100 includes at least an expected device modeling system 102. In some embodiments, the example system 100 optionally includes at least one user device 104, optionally includes at least one third-party data system 106, and/or optionally includes at least one target device 108. In some embodiments, the system 100 optionally includes at least one communications network 110 that enables transmission of data between one or more subsystem(s) and/or device(s) of the system 100.

The expected device modeling system 102 includes one or more computer(s) embodied in hardware, software, firmware, and/or a combination thereof. In some embodiments, the expected device modeling system 102 includes one or more application server(s), database server(s), enterprise computing terminal(s), and/or the like that are configured to perform the functionality described herein. Additionally or alternatively, in some embodiments, the expected device modeling system 102 includes one or more virtual computer(s) embodied in a software environment maintained via particular hardware, for example where the expected device modeling system 102 is maintained as a virtual environment on hardware of a central terminal supporting multiple software application(s). In some embodiments, the expected device modeling system 102 includes one or more hardware device(s) within the same physically defined space, such as a data warehouse, company headquarters, and/or the like associated with a particular entity. Alternatively or additionally, in some embodiments, the expected device modeling system 102 includes one or more hardware and/or software device(s) located remotely from one another and that communicate in conjunction with one another to provide the described functionality, for example embodied by one or more cloud computing system(s).

In some embodiments, the expected device modeling system 102 includes a plurality of sub-services that each support a portion of the functionality performed by the expected device modeling system 102. In some such embodiments, the plurality of sub-services may each be embodied by different hardware, software, firmware, and/or any combination thereof. Alternatively or additionally, in some embodiments, one or more of the sub-services share particular hardware, software, firmware, and/or any combination thereof. For example, in some embodiments, the expected device modeling system 102 embody specially-configured software applications executed on shared hardware.

In some embodiments, the expected device modeling system 102 supports modeling of expected device attribute(s) based at least in part on one or more device identifier(s). For example, in some embodiments, the expected device modeling system 102 supports functionality for generating expected device attributes utilizing at least one specially configured model, for example an expected device attribute model, for outputting. Additionally or alternatively, in some embodiments, the expected device modeling system 102 supports functionality for receiving device identifier(s), for example via transmission by one or more device(s), automatic detection via software executed process(es), and/or automatic identification via image processing. In some embodiments, the expected device modeling system 102 embodies an enterprise terminal specially configured to execute software application(s) for modeling expected device attribute(s) based at least in part on received device identifier(s). Additionally or alternatively, in some embodiments, the expected device modeling system 102 embodies one or more remote server(s) that provide such functionality to a user device and/or for rendering to the user device, such as the user device 104. For example, in some embodiments, the expected device modeling system 102 embodies a backend system that performs functionality requested (e.g., via one or more data transmission(s)) by the user device 104. In this regard, the user device 104 may embody an end point for displaying data generated by the expected device modeling system 102, and/or derived from such data.

The optional third-party data system 106 includes one or more computer(s) embodied in hardware, software, firmware, and/or any combination thereof. In some embodiments, the third-party data system 106 includes one or more application server(s), database server(s), enterprise computing terminal(s), and/or the like, that are configured to perform the functionality described herein. Additionally or alternatively, in some embodiments the third-party data system 106 includes one or more virtual computer(s) embodied in a software environment on particular hardware. In some embodiments, some or all of the third-party data system 106 is within the same physically defined space, such as a data warehouse, a company headquarters, and/or the like. Additionally or alternatively, in some embodiments, the third-party data system 106 includes one or more cloud computer(s) located remotely from one another that communicate in conjunction with one another to provide the described functionality. In some embodiments, the third-party data system 106 includes a plurality of sub-services that each provide a portion of the functionality performed by the third-party data system 106. In some such embodiments, the plurality of sub-services are each embodied by different hardware, software, firmware, and/or a combination thereof. Additionally or alternatively, in some embodiments, one or more of the sub-services share particular hardware, software, firmware, and/or a combination thereof.

In some embodiments, the third-party data system 106 supports maintenance of data utilized by the expected device modeling system 102 for modeling expected device attribute(s) associated with a particular device. In some embodiments, the third-party data system 106 maintains one or more device identifier(s) associated with particular device attribute(s), for example device identifier(s) associated with particular device make(s), model(s), and/or the like. For example, in some embodiments, the third-party data system 106 maintains data embodying a device identifier and associated actual device characteristic for training one or more model(s), such as an expected device attribute model. Alternatively or additionally, in some embodiments, the third-party data system 106 includes one or more server(s), computer(s), and/or system(s) that provide device identifier(s) associated with a device. Non-limiting examples of a user device 106 include a smartphone, a tablet, a laptop, a personal computer, a smart television, an Internet-of-Things enabled device, a smart assistant, and/or the like.

Alternatively or additionally, in some embodiments, the third-party data system 106 supports functionality associated at least with inputting at least one device identifier and/or receiving data resulting from processing of the at least one device identifier. In some embodiments, the third-party data system 106 includes at least one end user terminal that is configured to cause rendering to a display of a user interface for inputting the at least one device identifier. For example, in some embodiments, the third-party data system 106 includes or embodies an enterprise tablet or enterprise computing system located at a retail location, such as a carrier location, mobile device retail location, and/or the like, is accessible for public use. The third-party data system 106 may communicate with the expected device modeling system 102 to transmit at least one device identifier for processing, and/or to receive, in response to transmission of the at least one identifier, expected device attribute(s) and/or other data associated with or derived from such expected device attribute(s), such as an expected device buyback value.

The optional user device 104 includes one or more computer(s) embodied in hardware, software, firmware, and/or any combination thereof. In some embodiments, the user device 104 includes one or more end user device(s) that receive(s) data from an end user, display(s) data to an end user, and/or otherwise provides user-facing functionality. In some embodiments, the user device 104 executes a user-facing application that provides access to the expected device modeling system 102. The user-facing application in some embodiments includes a native application executed on the user device 104, in other embodiments the user-facing application includes a web-application executed on a browser application via the user device 104. In some embodiments, the user device 104 is utilized by an end user to request and/or initiate modeling of expected device attribute(s) for a particular device.

The target device 108 includes one or more computer(s) embodied in hardware, software, firmware, and/or any combination thereof. In some embodiments, the target device 108 embodies a device for which expected device attribute(s) are to be generated, for example via the expected device modeling system 102. In some embodiments, the target device 108 embodies an end user device configured to be used and/or communicable with the expected device modeling system 102, and/or identifiable via the expected device modeling system 102. Non-limiting examples of a target device 108 include a smartphone, a tablet, a laptop, a personal computer, a smart television, an Internet-of-Things enabled device, a smart assistant, and/or the like.

In some embodiments, the target device 108 supports functionality for identifying device identifiers associated with the target device 108. For example, in some embodiments, the target device 108 is configured to enable execution of at least one software request. The software request in some embodiments is initiated or otherwise generated by the expected device modeling system 102, for example, and transmitted to the target device 108. In some embodiments, the software request triggers execution of one or more software-implemented process(es) that identify device identifier(s) associated with the target device 108. In some such embodiments, the device identifier(s) embody software identifier(s) maintained via the target device 108. Additionally or alternatively, in some embodiments, the device identifier(s) embody hardware identifier(s) associated with the hardware of the target device 108, for example which may be retrievable via corresponding software and/or firmware of the target device 108 or otherwise maintained for retrieval via the target device 108. In some embodiments, the target device 108 may be inert or may otherwise not be available for software communication therewith, and the physical condition of the target device may include one or more identifiers (e.g., a serial number and/or IMEI printed on the case).

In some embodiments, the various devices of the system 100 over a communications network 110. For example, in some embodiments, the expected device modeling system 102 is communicable with the optional user device 104, the optional third-party data system 106, and the optional target device 108, via Wi-Fi, the Internet, or another public or private communications network that may span a large area. In some such embodiments, the devices communicate via a shorter-range communications network, for example Bluetooth low energy or the like. Alternatively or additionally, in some embodiments devices communicate over any wired, wireless, long-range, and/or short-range wireless communications network(s).

The communications network 110 as described in some embodiments is embodied in any of a myriad of network configurations. In some embodiments, the communications network 110 embody a public network (e.g., the Internet). In some embodiments, the communications network 110 embodies a private network (e.g., an internal, localized, or closed-off network between particular devices). In some other embodiments, the communications network 110 embody a hybrid network (e.g., a network enabling internal communications between particular connected devices and external communications with other devices). The communications network 110 in some embodiments includes one or more base station(s), relay(s), router(s), switch(es), cell tower(s), communications cable(s) and/or associated routing station(s), and/or the like. In some embodiments, the communications network 110 includes one or more user-controlled computing device(s) (e.g., a user owner router and/or modem) and/or one or more external utility devices (e.g., Internet service provider communication tower(s) and/or other device(s)).

The computing device(s) each may communicate over a whole or a portion of one or more communications network(s), such as the communications network 110. For example, each of the components of the system communicatively coupled to transmit data to and/or receive data from, for example, one another over the same or different wireless or wired networks embodying the communications network(s). Such configuration(s) include, without limitation, a wired or wireless Personal Area Network (PAN), Local Area Network (LAN), Metropolitan Area Network (MAN), Wide Area Network (WAN), and/or the like. Additionally, while FIG. 1 illustrate certain system entities as separate, standalone entities communicating over the communications network(s), the various embodiments are not limited to this particular architecture. In other embodiments, one or more computing entities share one or more components, hardware, and/or the like, or otherwise are embodied by a single computing device such that connection(s) between the computing entities are over the communications network(s) are altered and/or rendered unnecessary. Alternatively or additionally still, in some embodiments the communications network 110 enable communication to one or more other computing device(s) not depicted, for example client device(s) for accessing functionality of any of the subsystems therein via native and/or web-based application(s), and/or the like.

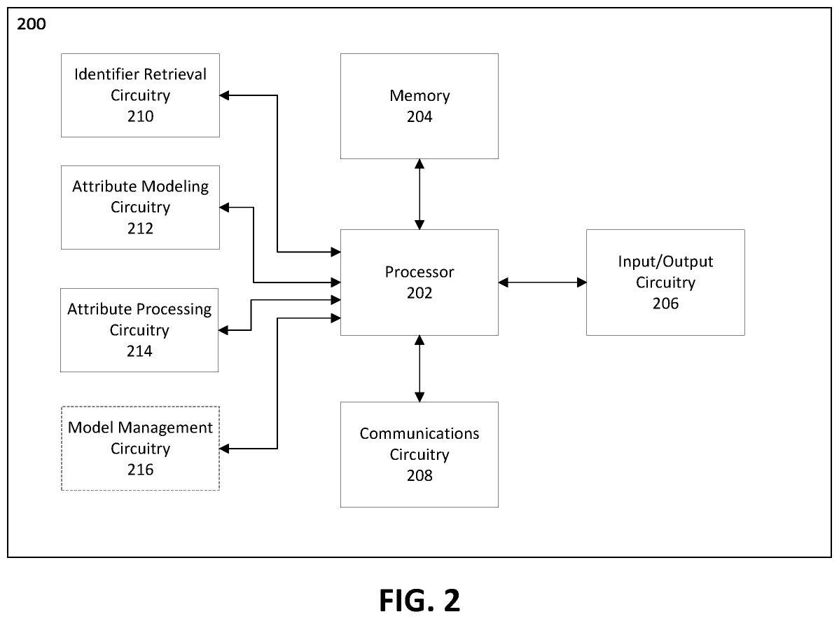

FIG. 2 illustrates a block diagram of an example apparatus that may be specially configured in accordance with an example embodiment of the present disclosure. Specifically, FIG. 2 illustrates an example expected attribute modeling apparatus 200 (“apparatus 200”) specially configured in accordance with at least one example embodiment of the present disclosure. In some embodiments, the expected device modeling system 102, and/or a portion thereof, is embodied by one or more system(s), device(s), and/or the like, such as the apparatus 200 as depicted and described in FIG. 2. The apparatus 200 includes processor 202, memory 204, input/output circuitry 206, communications circuitry 208, identifier retrieval circuitry 210, attribute modeling circuitry 212, attribute processing circuitry 214, and/or optional model management circuitry 216. In some embodiments, the apparatus 200 is configured, using one or more of the sets of circuitry 202, 204, 206, 208, 210, 212, 214, and/or 216, to execute and perform one or more of the operations described herein.

In general, the terms computing entity (or “entity” in reference other than to a user), device, system, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably. In this regard, the apparatus 200 embodies a particular, specially configured computing entity transformed to enable the specific operations described herein and provide the specific advantages associated therewith, as described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), network interface(s), storage medium(s), and/or the like, to perform their associated functions, such that duplicate hardware is not required for each set of circuitry. The use of the term “circuitry” as used herein with respect to components of the apparatuses described herein should therefore be understood to include particular hardware configured to perform the functions associated with the particular circuitry as described herein.

Particularly, the term “circuitry” should be understood broadly to include hardware and, in some embodiments, software for configuring the hardware. For example, in some embodiments, “circuitry” includes processing circuitry, storage media, network interfaces, input/output devices, and/or the like. Alternatively or additionally, in some embodiments, other elements of the apparatus 200 provide or supplement the functionality of another particular set of circuitry. For example, the processor 202 in some embodiments provides processing functionality to any of the sets of circuitry, the memory 204 provides storage functionality to any of the sets of circuitry, the communications circuitry 208 provides network interface functionality to any of the sets of circuitry, and/or the like.

In some embodiments, the processor 202 (and/or co-processor or any other processing circuitry assisting or otherwise associated with the processor) is/are in communication with the memory 204 via a bus for passing information among components of the apparatus 200. In some embodiments, for example, the memory 204 is non-transitory and may include, for example, one or more volatile and/or non-volatile memories. In other words, for example, the memory 204 in some embodiments includes or embodies an electronic storage device (e.g., a computer readable storage medium). In some embodiments, the memory 204 is configured to store information, data, content, applications, instructions, or the like, for enabling the apparatus 200 to carry out various functions in accordance with example embodiments of the present disclosure.

The processor 202 may be embodied in a number of different ways. For example, in some example embodiments, the processor 202 includes one or more processing devices configured to perform independently. Additionally or alternatively, in some embodiments, the processor 202 includes one or more processor(s) configured in tandem via a bus to enable independent execution of instructions, pipelining, and/or multithreading. The use of the terms “processor” and “processing circuitry” should be understood to include a single core processor, a multi-core processor, multiple processors internal to the apparatus 200, and/or one or more remote or “cloud” processor(s) external to the apparatus 200.

In an example embodiment, the processor 202 is configured to execute instructions stored in the memory 204 or otherwise accessible to the processor. Alternatively or additionally, the processor 202 in some embodiments is configured to execute hard-coded functionality. As such, whether configured by hardware or software methods, or by a combination thereof, the processor 202 represents an entity (e.g., physically embodied in circuitry) capable of performing operations according to an embodiment of the present disclosure while configured accordingly. Alternatively or additionally, as another example in some example embodiments, when the processor 202 is embodied as an executor of software instructions, the instructions specifically configure the processor 202 to perform the algorithms embodied in the specific operations described herein when such instructions are executed.

As one particular example embodiment, the processor 202 is configured to perform various operations associated with modeling of expected device attribute(s) associated with a particular device. In some embodiments, the processor 202 includes hardware, software, firmware, and/or a combination thereof, that receives at least one device identifier associated with a device. Additionally or alternatively, in some embodiments, the processor 202 includes hardware, software, firmware, and/or a combination thereof, that generates at least one expected device attribute associated with the device. In some such embodiments, the processor 202 includes hardware, software, firmware, and/or a combination thereof, that applies the at least one device identifier to an expected device attribute model that determines the at least one expected device attribute associated with the device. Additionally or alternatively, in some embodiments, the processor 202 includes hardware, software, firmware, and/or a combination thereof, that outputs the at least one expected device attribute. Additionally or alternatively, in some embodiments, the processor 202 includes hardware, software, firmware, and/or a combination thereof, that initiates at least one computer-implemented process based at least in part on the at least one expected device attribute.

In some embodiments, the apparatus 200 includes input/output circuitry 206 that provides output to the user and, in some embodiments, to receive an indication of a user input. In some embodiments, the input/output circuitry 206 is in communication with the processor 202 to provide such functionality. The input/output circuitry 206 may comprise one or more user interface(s) and in some embodiments includes a display that comprises the interface(s) rendered as a web user interface, an application user interface, a user device, a backend system, or the like. In some embodiments, the input/output circuitry 206 also includes a keyboard, a mouse, a joystick, a touch screen, touch areas, soft keys a microphone, a speaker, or other input/output mechanisms. The processor 202 and/or input/output circuitry 206 comprising the processor may be configured to control one or more functions of one or more user interface elements through computer program instructions (e.g., software and/or firmware) stored on a memory accessible to the processor (e.g., memory 204, and/or the like). In some embodiments, the input/output circuitry 206 includes or utilizes a user-facing application to provide input/output functionality to a client device and/or other display associated with a user. In some embodiments, the input/output circuitry 206 includes hardware, software, firmware, and/or a combination thereof, that facilitates simultaneously display of particular data via a plurality of different devices.

In some embodiments, the apparatus 200 includes communications circuitry 208. The communications circuitry 208 includes any means such as a device or circuitry embodied in either hardware or a combination of hardware and software that is configured to receive and/or transmit data from/to a network and/or any other device, circuitry, or module in communication with the apparatus 200. In this regard, in some embodiments the communications circuitry 208 includes, for example, a network interface for enabling communications with a wired or wireless communications network. Additionally or alternatively in some embodiments, the communications circuitry 208 includes one or more network interface card(s), antenna(s), bus(es), switch(es), router(s), modem(s), and supporting hardware, firmware, and/or software, or any other device suitable for enabling communications via one or more communications network(s). Additionally or alternatively, the communications circuitry 208 includes circuitry for interacting with the antenna(s) and/or other hardware or software to cause transmission of signals via the antenna(s) or to handle receipt of signals received via the antenna(s). In some embodiments, the communications circuitry 208 enables transmission to and/or receipt of data from a client device, capture device, and/or other external computing device in communication with the apparatus 200.

In some embodiments, the apparatus 200 includes identifier retrieval circuitry 210. The identifier retrieval circuitry 210 includes hardware, software, firmware, and/or a combination thereof, that supports various functionality associated with receiving device identifier(s). For example, in some embodiments, the identifier retrieval circuitry 210 includes hardware, software, firmware, and/or a combination thereof, that receives at least one device identifier from a target device for which expected device attribute(s) are to be modeled. Additionally or alternatively, in some embodiments, the identifier retrieval circuitry 210 includes hardware, software, firmware, and/or a combination thereof, that initiates one or more software request(s) for execution on a device to retrieve at least one device identifier associated with the device. Additionally or alternatively, in some embodiments, the identifier retrieval circuitry 210 includes hardware, software, firmware, and/or a combination thereof, that processes at least one captured image utilizing one or more image process(es), for example utilizing computer vision model(s), to identify at least one device identifier from the at least one captured image. In various embodiments, the apparatus 200 may include image capture hardware (e.g., one or more cameras) as part of the input/output circuitry 206. The identifier device identifier(s) may be extracted from captured image(s) representing an external or visible portion of the device. In some embodiments, the identifier retrieval circuitry 210 includes a separate processor, specially configured field programmable gate array (FPGA), or a specially programmed application specific integrated circuit (ASIC).

In some embodiments, the apparatus 200 includes attribute modeling circuitry 212. The attribute modeling circuitry 212 includes hardware, software, firmware, and/or a combination thereof, that supports various functionality associated with generating at least one expected device attribute modeled for a particular device. For example, in some embodiments, the attribute modeling circuitry 212 includes hardware, software, firmware, and/or a combination thereof, that applies at least one device identifier to an expected device attribute model. Additionally or alternatively, in some embodiments, the attribute modeling circuitry 212 includes hardware, software, firmware, and/or a combination thereof, that determines and/or otherwise generates at least one expected device attribute associated with at least one device. In some embodiments, the attribute modeling circuitry 212 includes a separate processor, specially configured field programmable gate array (FPGA), or a specially programmed application specific integrated circuit (ASIC).

In some embodiments, the apparatus 200 includes attribute processing circuitry 214. The attribute processing circuitry 214 includes hardware, software, firmware, and/or a combination thereof, that supports processing of expected device attribute(s) modeled associated with a particular device. For example, in some embodiments, the attribute processing circuitry 214 includes hardware, software, firmware, and/or a combination thereof, that initiates at least one computer-implemented process based at least in part on at least one expected device attribute modeled associated with a device. Additionally or alternatively, in some embodiments, the attribute processing circuitry 214 includes hardware, software, firmware, and/or a combination thereof, that outputs at least one expected device attribute for further processing. Additionally or alternatively, in some embodiments, the attribute processing circuitry 214 includes hardware, software, firmware, and/or a combination thereof, that identifies image data corresponding to at least one expected device attribute, and/or causes rendering of a user interface including at least the image data. Additionally or alternatively, in some embodiments, the attribute processing circuitry 214 includes hardware, software, firmware, and/or a combination thereof, that causes rendering of a user interface including at least a textual description of at least one expected device attribute. Additionally or alternatively, in some embodiments, the attribute processing circuitry 214 includes hardware, software, firmware, and/or a combination thereof, that receives an image representation of a device, for example by capturing the image representation or retrieving the image representation, processes the image representation to determine at least one actual device attribute associated with the device, generating comparison data representing results of a comparison of the actual device attribute with the at least one expected device attribute, and/or outputting the comparison data. In some embodiments, the attribute processing circuitry 214, either alone or in combination with one or more other elements of the apparatus 200, may be configured to update, create, or otherwise maintain a database of known device identifiers and/or information associated with such device identifiers (e.g., known and/or predicted attributes). Additionally or alternatively, in some embodiments, the attribute processing circuitry 214 includes hardware, software, firmware, and/or a combination thereof, that stores at least one expected device attribute associated with a device. In some embodiments, the attribute processing circuitry 214 includes a separate processor, specially configured field programmable gate array (FPGA), or a specially programmed application specific integrated circuit (ASIC).

In some embodiments, the apparatus 200 optionally includes model management circuitry 216. The model management circuitry 216 includes hardware, software, firmware, and/or a combination thereof, that supports training, maintenance, and/or storing of one or more specially configured model(s). For example, in some embodiments, the model management circuitry 216 includes hardware, software, firmware, and/or a combination thereof, that identifies a training data set utilized to train an expected device attribute model. In some such embodiments, the model management circuitry 216 retrieves device identifier(s) and corresponding actual device attribute(s) for training an expected device attribute model. Additionally or alternatively, in some embodiments, the model management circuitry 216 includes hardware, software, firmware, and/or a combination thereof, that trains an expected device attribute model based at least in part on identified training data. Additionally or alternatively, in some embodiments, the model management circuitry 216 includes hardware, software, firmware, and/or a combination thereof, that retrieves an expected device attribute model for use in modeling at least one expected device attribute. Additionally or alternatively, in some embodiments, the model management circuitry 216 includes hardware, software, firmware, and/or a combination thereof, that receives feedback attribute data associated with at least one particular expected device attribute, and updating training of an expected device attribute model based at least in part on the feedback attribute data. In some embodiments, the model management circuitry 216 includes a separate processor, specially configured field programmable gate array (FPGA), or a specially programmed application specific integrated circuit (ASIC).

Additionally or alternatively, in some embodiments, two or more of the sets of circuitries 202-216 are combinable. Alternatively or additionally, in some embodiments, one or more of the sets of circuitry perform some or all of the functionality described associated with another component. For example, in some embodiments, two or more of the sets of circuitry 202-216 are combined into a single module embodied in hardware, software, firmware, and/or a combination thereof. Similarly, in some embodiments, one or more of the sets of circuitry, for example the identifier retrieval circuitry 210, the attribute modeling circuitry 212, the attribute processing circuitry 214, and/or the model management circuitry 216, is/are combined with the processor 202, such that the processor 202 performs one or more of the operations described above with respect to each of these sets of circuitry 210-216.

### Example Data Environments of the Disclosure

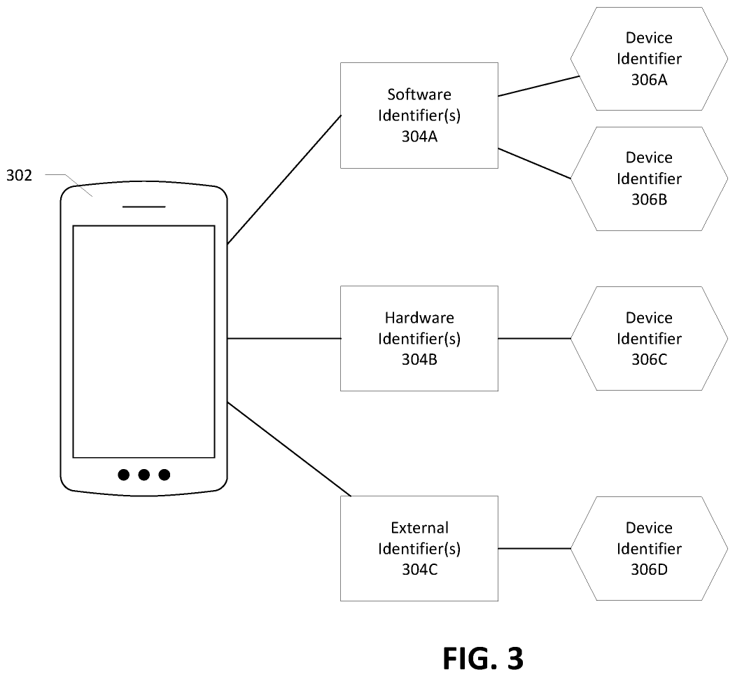

FIG. 3 illustrates an example visualization of device identifiers associated with a particular device in accordance with at least some example embodiments of the present disclosure. Specifically, FIG. 3 illustrates a visualization of device identifiers associated with a particular device 302. In some embodiments, the device identifiers are each maintained as electronically managed data identified from, on, or by processing one or more aspect(s) of the device 302. In some embodiments, the device 302 embodies a smartphone or other user device submitted or otherwise identified for processing. For example, in one example context, the device 302 embodies a device for processing as part of a device return service, repair service, replacement service, insurance service, and/or the like.

In some embodiments, the device 302 is associated with one or more software identifier(s) 304A. In some embodiments, the software identifier(s) 304A include electronically managed data that unique identifies the device 302, for example based at least in part on data identifier(s) assigned to the device 302. In some embodiments, the software identifier(s) 304A include one or more data identifier(s) generated by, stored via, and/or otherwise maintained by an operating system of the device 302. Alternatively or additionally, in some embodiments, the software identifier(s) 304A include at least one predetermined data value stored via a memory of the device 302 and retrievable via particular software application(s) executed on the device 302. The device 302 may be associated with any number of software identifier(s) 304A simultaneously, for example device identifier 306A (e.g., representing a software version of a MEID) and 306B (e.g., representing an eSIM identifier). In some embodiments, the software identifier(s) 302A include one or more data value(s) representing a software-stored version of an alphanumeric, numeric, and/or alphabetical identifier(s) assigned to the device 302 and printed on the device 302 and/or otherwise associated with hardware of the device 302, such that the software identifier embodies a redundant version of another device identifier. Non-limiting examples of a software identifier include an IP address, an eSIM identifier, a MEID, a software-stored serial number and/or IMEI, and/or the like.

In some embodiments, the device 302 is associated with one or more hardware identifier(s) 304B. In some embodiments, the hardware identifier(s) 304B include one or more device identifier(s) assigned to or that otherwise uniquely represents one or more hardware component(s) of the device 302. In some embodiments, the hardware identifier(s) 304B include a data value assigned to a memory, SIM card or eSIM, processor, or other hardware component of the device 302. Alternatively or additionally, in some embodiments, the hardware identifier(s) 304B include a unique alphanumeric, alphabetical, and/or numerical identifier that uniquely identifies a hardware set of the device 302. The device 302 may be associated with any number of hardware identifier(s) 304B simultaneously, for example device identifier 306C (e.g., representing an IMEI stored via a memory of the device 302). Non-limiting examples of a hardware identifier include an IMEI assigned to a device, a serial number or SKU assigned to a component of the device, a hardware unique identifier for at least one hardware component of a device, a hardware address, a MAC address, another burned-in address associated with the device, and/or the like. It will be appreciated that the hardware identifier(s) 304B in some embodiments are identified via software, firmware, and/or other request(s) executed on the device 302. Alternatively or additionally, in some embodiments, one or more of the hardware identifier(s) 304B is identifiable via physical inspection of the external or internal portions of the device 302.

In some embodiments, the device 302 is associated with one or more external identifier(s) 304C. In some embodiments, the external identifier(s) 304C includes one or more alphanumeric, numeric, and/or alphabetical identifier associated with the device 302 that is available via physical inspection of the device 302 and/or associated packaging and/or other object(s). For example, in some embodiments, the external identifier(s) 304C include marking(s) indicating a particular configuration of the hardware and/or software of the device 302, such as a memory storage size, an IMEI assigned to the device, a serial number assigned to the device, a SKU assigned to the device, a device make, and/or the like. The device 302 may be associated with any number of external identifier(s) 304C simultaneously, for example device identifier 306D (e.g., representing a printed memory capacity text on the back of the device 302). Alternatively or additionally, in some embodiments, the external identifier(s) 304C include retailer, manufacturer, and/or other related identifier(s) associated with distribution of the device 302, for example a SKU associated with the device 302. In some embodiments, external identifiers may be inclusive of certain hardware and/or software identifiers.

It will be appreciated that a particular device may be associated with any of the described device identifier types individually and/or in combination, and in some embodiments, not all identifiers may be outwardly detectable, such that the models and algorithms described herein may operate using a subset including one or more identifiers. For example, in some embodiments the detected identifiers associated with a device 302 include only software identifiers 304A. In some embodiments the detected identifiers associated with a device 302 include only hardware identifiers 304B. In some embodiments the detected identifiers associated with a device 302 include only external identifiers 304C. Alternatively or additionally, in some embodiments, the detected identifiers associated with a device 302 include only software identifiers 304A and external identifiers 304C. Alternatively or additionally, in some embodiments, the detected identifiers associated with a device 302 include only hardware identifiers 304B and external identifiers 304C. Alternatively or additionally, in some embodiments, the detected identifiers associated with a device 302 include only software identifiers 304A and hardware identifiers 304B. Alternatively or additionally, in some embodiments, the device is associated with each of the described device identifier types. Any identifiable device identifier may be identified, retrieved, and/or otherwise received for further processing, for example for use in modeling expected device attribute(s) as described herein.

In some embodiments, one or more device identifier(s) is received in response to manual user input (e.g., via input/output circuitry 206 associated with an apparatus 200). For example, in some embodiments, one or more device identifier(s) (e.g., a SKU, Serial Number, and/or an IMEI) is received via user input to a user interface configured for display by the apparatus 200. In some embodiments, the user interface is outputted to a display of the apparatus 200. Alternatively or additionally, in some embodiments, the apparatus 200 transmits data to cause rendering of the user interface at a remote device. For example, in some embodiments, the apparatus 200 provides or causes rendering at an end user device or terminal of a web portal enabling input of the at least one device identifier for processing. In some embodiments, the user interface includes one or more interface control(s) configured to receive user input of at least one device identifier, and in some such embodiments transmit the inputted at least one device identifier to the apparatus 200 for processing as described herein. In this regard, it should be appreciated that device identifier(s) may be manually inputted, automatically identified, or any combination thereof (e.g., at least one manually identified device identifier and at least one automatically identified device identifier).

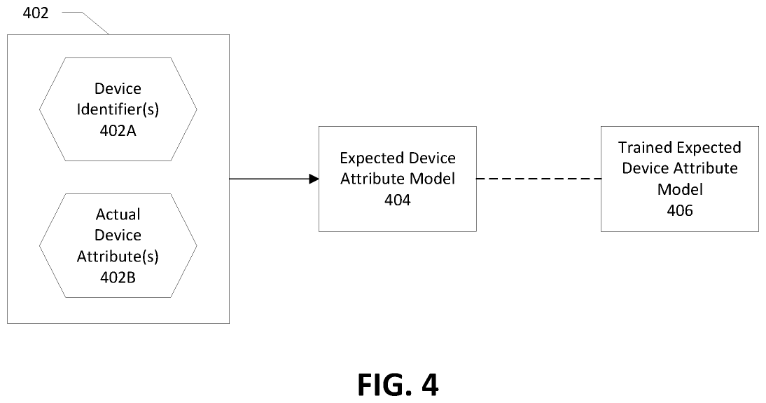

FIG. 4 illustrates an example visualization of training an expected device attribute model in accordance with at least some example embodiments of the present disclosure. Specifically, FIG. 4 depicts training of an expected device attribute model 404 utilizing a training data set 402. The training of the expected device attribute model 404 results in a trained version of the model, for example embodied by the trained expected device attribute model 406. In some embodiments, the apparatus 200 stores a version of the expected device attribute model 404, such that as training of the stored version of the expected device attribute model is updated towards to the trained expected device attribute model 406. The apparatus 200 may subsequently maintain the expected device attribute model 406 for use in modeling one or more expected device attribute(s).

In some embodiments, the expected device attribute model 404 is trained based at least in part on parsed data value(s) and/or portion(s) from the device identifier(s) 402A and corresponding actual device attribute(s) 402B. For example, in some embodiments, portions of the device identifier(s) 402A is/are parsed into a feature vector, with each feature vector corresponding to a particular data value for a particular device attribute to be processed. In this regard, the parsed portions of the device identifier(s) 402A may each represent a feature vector corresponding to the device identifier of the device identifier(s) 402A for processing. In some embodiments, the feature vector includes one or more feature value(s) embodied by an encoded version of the data value parsed from the device identifier(s) 402A. For example, in some embodiments, a parsed or otherwise extracted feature value is processed utilizing label encoding, natural language processing, and/or other conversion algorithm(s) to convert a data value into a standardized machine-readable representation processable by the expected device attribute model 404 during training. In some embodiments, data values may be classified as either a feature utilized in machine learning or a contextual label. In some embodiments, the feature vector is identified based at least in part on one or more feature extraction algorithm(s) that identify the useful portion(s) of a particular device identifier. In some such embodiments, one or more of the portion(s) of a device identifier may be disregarded as not significant or otherwise intended for processing via a particular machine learning model, for example an expected device attribute model.

In some embodiments, the expected device attribute model 404 embodies one or more machine learning model(s), neural network model(s), artificial intelligence model(s), statistical model(s), algorithmic model(s), and/or the like, or a combination thereof. In some embodiments, the expected device attribute model 404 includes one or more specially trained classification model(s) that classifies particular data identifier(s) into a device having particular expected characteristic(s) represented by expected device attribute(s). For example, in some embodiments, the expected device attribute model 404 includes or is embodied by one or more specially configured K-Nearest Neighbors model(s) that classifies device identifier(s), and/or particular portions of such device identifier(s) representing particular feature value(s), to expected device attribute(s). Additionally or alternatively, in some embodiments, the expected device attribute model 404 embodies one or more artificial intelligence model(s). Additionally or alternatively, in some embodiments, the expected device attribute model 404 embodies one or more statistical and/or algorithmic model(s) to be fit utilizing one or more portion(s) of data.

As depicted, the training data set 402 includes one or more device identifier(s) 402A and one or more actual device attribute(s) 402B. In some embodiments, the training data set 402 is in whole or in part automatically determined, for example by one or more system(s) that extract, determine, and/or otherwise retrieve device identifier(s) and corresponding actual device attribute(s) for one or more device(s). Additionally or alternatively, in some embodiments, the training data set 402 is in whole or in part determined, submitted, and/or otherwise identified and/or submitted by a user. For example, the user may identify actual device attribute(s) for one or more particular device(s) for storage associated with manually-determined and/or data-driven determined device identifier(s) for that device. In this regard, the training data set 402 includes one or more data object(s), record(s), and/or the like that link device identifier(s) 402A with corresponding actual device attribute(s) 402B for the actual devices having such device identifier(s) 402A. The complete training data set 402 may represent a source of truth for any number of actual device attribute(s) 402B and associated device identifier(s) 402A for devices having such attributes, such that the expected device attribute model may extract pattern(s), trend(s), and/or the like from such links between the device identifier(s) and corresponding actual device attribute(s).

It will be appreciated that the expected device attribute model 404 may be trained into the trained expected device attribute model 406 utilizing any of a myriad of method(s). For example, in some embodiments, the training data set 402 is segmented into a sub-subset representing a training set, a subset representing a test set, and/or a subset representing a validation set. Additionally or alternatively, in some embodiments, the expected device attribute model 404 is trained in stage(s), and/or continuously updated as new training data is identified and/or otherwise received.

It should be appreciated that the training of the trained expected device attribute model 406 may be performed utilizing any of a myriad of known and/or customized environments, tools, libraries, and/or the like. For example, in some embodiments the trained expected device attribute model 406 is trained utilizing the Python pandas suite of tools. Additionally or alternatively, in some embodiments, the trained expected device attribute model 406 is trained utilizing a MATLAB training suite. In yet other embodiments, the trained expected device attribute model 406 is trained utilizing a customized software application, applet, and/or the like.

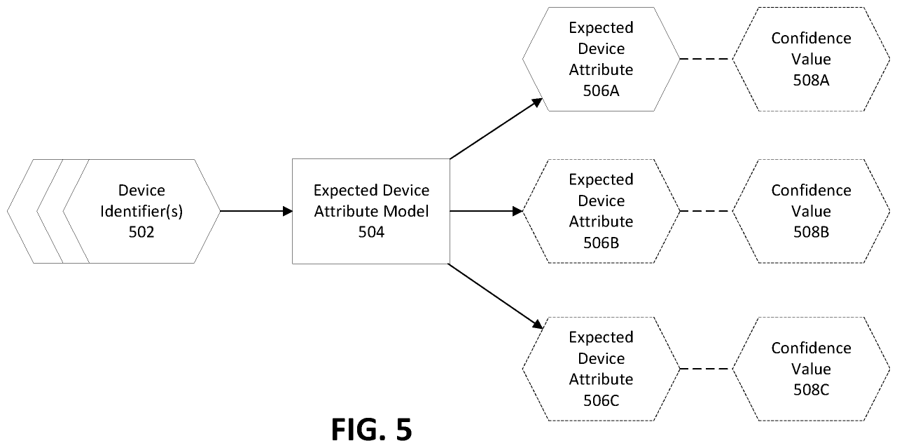

FIG. 5 illustrates an example visualization of modeling expected device attributes utilizing a trained model in accordance with at least some example embodiments of the present disclosure. Specifically, FIG. 5 depicts modeling of expected device attribute(s) utilizing an expected device attribute model 504. In some such embodiments, the expected device attribute model 504 embodies a specially trained model based at least in part on one or more data set(s). For example, in some embodiments, the expected device attribute model 504 embodies or includes the trained expected device attribute model 406 trained based at least in part on the training data set 402. In some embodiments, the expected device attribute model 504 is maintained and/or utilized by the apparatus 200 for modeling one or more expected device attribute(s).

In some embodiments, the apparatus 200 applies one or more device identifier(s) 502 to the expected device attribute model 504. In some embodiments, the one or more device identifier(s) 502 is/are identified and/or otherwise received for a particular device for processing. For example, in some embodiments, the one or more device identifier(s) 502 are received in response to software request(s) executed on the device. Additionally or alternatively, in some embodiments, one or more of the device identifier(s) 502 is/are received in response to manual input, image processing of an image representation of the device, and/or the like. The device identifier(s) 502 may include one or more software identifier(s), hardware identifier(s), external identifier(s), and/or any combination thereof.

In some embodiments, the device identifier(s) 502 is/are directly inputted to the expected device attribute model 504. In other embodiments, the device identifier(s) 502 are processed to generate one or more feature vectors that is/are applied to the expected device attribute model 504. For example, in some embodiments, the apparatus 200 parses the device identifier(s) 502 to generate a feature vector including particular data values based on the portion(s) parsed from the device identifier(s) 502. Additionally or alternatively, in some embodiments, the apparatus 200 performs label encoding on one or more portion(s) parsed and/or otherwise extracted from the device identifier(s) 502 to generate feature values for particular feature(s) for processing by the expected device attribute model 504. The resulting feature vector(s) including label encoded feature value(s) subsequently may be applied to the expected device attribute model 504.

In some embodiments, the expected device attribute model 504 models expected device attribute(s) by generating one or more expected device attribute(s). In some embodiments, the expected device attribute(s) represent device attribute(s) predicted to be associated with the device corresponding to the device identifier(s) applied to the expected device attribute model 504. For example, as illustrated, in some embodiments the expected device attribute model 504 generates one or more expected device attribute(s) 506A-506C based at least in part on the device identifier(s) 502 corresponding to a particular device. In this regard, the expected device attributes generated via the expected device attribute model 504 represent predicted device characteristics expected for a particular device based on the corresponding to the device identifier(s) 502. For example, as depicted, the expected device attribute model 504 generates any number of expected device attribute(s), such as expected device attribute 506A, and optionally expected device attribute 506B and/or expected device attribute 506C.

In some embodiments, the expected device attribute(s) 506A, 506B, and/or 506C represent physical characteristics expected for the device corresponding to the device identifier(s) 502. For example, in some embodiments, one or more of the expected device attribute(s) 506A, 506B, and/or 506C embody data representing a device color, a device make, a device model, and/or the like. Additionally or alternatively, in some embodiments, one or more of the expected device attribute(S) 506A, 506B, and/or 506C embody data representing a physical condition of a device. The physical condition may be selected from one of a plurality of candidate conditions (e.g., “new,” “like new,” “great,” “good,” “poor,” “very poor,” and/or the like). Additionally or alternatively, in some embodiments, the data indicating a physical condition of the device represents a particular visible and/or functional problem with the device (e.g., cracked screen, dent on the back, missing switch, and/or the like). In this regard, it will be appreciated that an expected device attribute may be generated that represents any visibly noticeable characteristic of a particular device. Such physical characteristic(s) may differ based at least in part on device type, make and/or model, and/or the like.

In some embodiments, the expected device attribute model 504 is configured to query at least one database based at least in part on one or more device identifier(s). For example, the expected device attribute model 504 in some embodiments queries a database of device condition(s) based at least in part on one or more device identifier(s), for example an IMEI, SKU, serial number, and/or the like. The query may retrieve corresponding data record(s), if stored to the database, utilizing such device identifier(s) as a key. The data record(s) may include expected device attribute(s) representing physical condition of a device and/or particular subcomponents thereof, for example whether a screen is cracked, whether any portion of the chassis is dented, and/or the like. In some embodiments, the database of device condition(s) is populated during device intake to a system associated with the apparatus 200, for example, which may be performed manually (e.g., via user input indicating physical condition(s) of or associated with a device, and/or automatically via one or more computer-implemented process(es), for example utilizing computer vision as described herein.

In some embodiments, the expected device attribute model 504 outputs generated expected device attribute(s), such as the expected device attributes 506A, 506B, and 506C, that are determined to most likely represent the value for a particular characteristic. For example, in some embodiments, the expected device attribute model 504 outputs expected device attribute(s) representing a determined highest probability device make, a highest probability device model, a highest probability device color, and/or the like. In some such embodiments, the expected device attribute may be output in a circumstance where the probability of the value represented by the expected device is highest, and/or at least satisfies a particular threshold.

Additionally or alternatively, in some embodiments, the expected device attribute model 504 generates confidence value(s) for different expected data attribute(s) representing different values for a particular device characteristic. For example, in some such embodiments, the apparatus 200 utilizes the expected device attribute model 504 to generate confidence value 508A representing a determined probability of an expected device attribute 506A (e.g., representing a first candidate device color), confidence value 508B representing a determined probability of an expected device attribute 506B (e.g., representing a second candidate device color), and confidence value 508C representing a determined probability of an expected device attribute 506C. Such embodiments may generate the probability of various different candidate options for a particular device characteristic represented by the different expected device attribute(s). In some embodiments, the expected device attributes correspond to particular device attributes that are determined based at least in part on the device identifier(s) 502 inputted to the expected device attribute model 504. In this regard, input of a first device identifier type (e.g., a SKU or serial number for example) may correspond to a first set of device attributes (e.g., color, capacity, storage), and input of a second device identifier type (e.g., an IMEI for example) may correspond to a second set of device attributes (e.g., make, model, and color). Any combination of device identifier(s) and device attribute(s) may be established.

In some such embodiments, the apparatus 200 and/or the expected device attribute model 504 compares the confidence value for one or more expected device attribute(s) with a confidence threshold. For example, in some embodiments, the apparatus 200 and/or the expected device attribute model 504 compares each confidence value 508A, 508B, and 508C with a confidence threshold to determine whether each such confidence value satisfies the confidence threshold. In some embodiments, the expected device attribute model 504 outputs the expected device attribute(s) corresponding to confidence value(s) that satisfy the confidence threshold, for example by exceeding the confidence threshold. Some such embodiments may output multiple expected device attribute(s) for a single device characteristic in circumstances where each is associated with a confidence value that satisfies the confidence threshold. For example, in some embodiments, the expected device attribute model 504 outputs each expected device attribute representing a possible value with a sufficient likelihood defined by a probability above the particular confidence threshold, such that the universe of possible values is limited to the highest probability possibilities for one or more device characteristic(s). Ambiguity resulting from multiple output expected device attribute(s) for a particular device characteristic may be resolved by and end user, for example via user input, and/or automatically utilizing one or more other computer-implemented process(es). In some embodiments, a user provides user input confirming which of the expected device attribute(s) having a sufficiently high confidence value (e.g., exceeding or otherwise satisfying the confidence threshold) matches an actual device attribute of the device. In some embodiments the expected device attribute model is updated based at least in part on the user input indicating which expected device attribute matches the actual device attribute of a particular device, for example to improve the ability of the expected device attribute model to generate links between the applied device identifier(s) and correct expected device attribute.

### Example Processes of the Disclosure

Having described example systems and apparatuses, data environments, and related data flows in accordance with the disclosure, example processes of the disclosure will now be discussed. It will be appreciated that each of the flowcharts depicts an example computer-implemented process that is performable by one or more of the apparatuses, systems, devices, and/or computer program products described herein, for example utilizing one or more of the specially configured components thereof.

The blocks indicate operations of each process. Such operations may be performed in any of a number of ways, including, without limitation, in the order and manner as depicted and described herein. In some embodiments, one or more blocks of any of the processes described herein occur in-between one or more blocks of another process, before one or more blocks of another process, in parallel with one or more blocks of another process, and/or as a sub-process of a second process. Additionally or alternatively, any of the processes in various embodiments include some or all operational steps described and/or depicted, including one or more optional blocks in some embodiments. With regard to the flowcharts illustrated herein, one or more of the depicted block(s) in some embodiments is/are optional in some, or all, embodiments of the disclosure. Optional blocks are depicted with broken (or “dashed”) lines. Similarly, it should be appreciated that one or more of the operations of each flowchart may be combinable, replaceable, and/or otherwise altered as described herein.

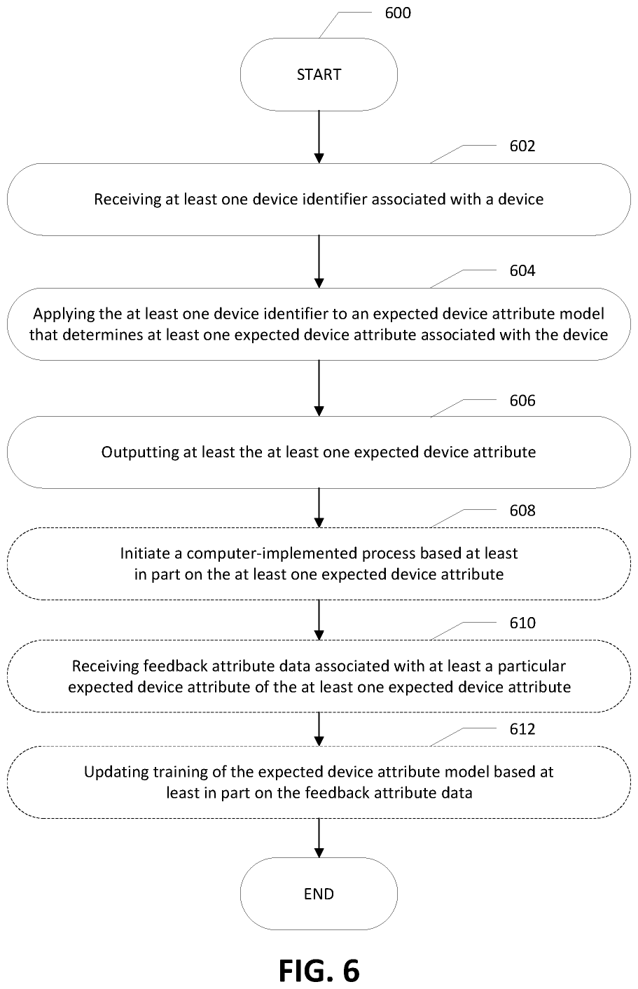

FIG. 6 illustrates a flowchart depicting example operations of a process for modeling expected device attributes in accordance with at least some example embodiments of the present disclosure. Specifically, FIG. 6 illustrates an example computer-implemented process 600. In some embodiments, the process 600 is embodied by computer program code stored on a non-transitory computer-readable storage medium of a computer program product configured for execution to perform the process as depicted and described. Alternatively or additionally, in some embodiments, the process 600 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data system, and/or the like. In some embodiments, the apparatus 200 may be configured to expose an API which other devices, such as the third-party data system, may call. The apparatus 200 may then receive one or more device identifier(s) from the other device(s) via the API, apply the device identifier(s) to the model, and output one or more expected attributes to the other device(s). For purposes of simplifying the description, the process 600 is described as performed by and from the perspective of the apparatus 200.

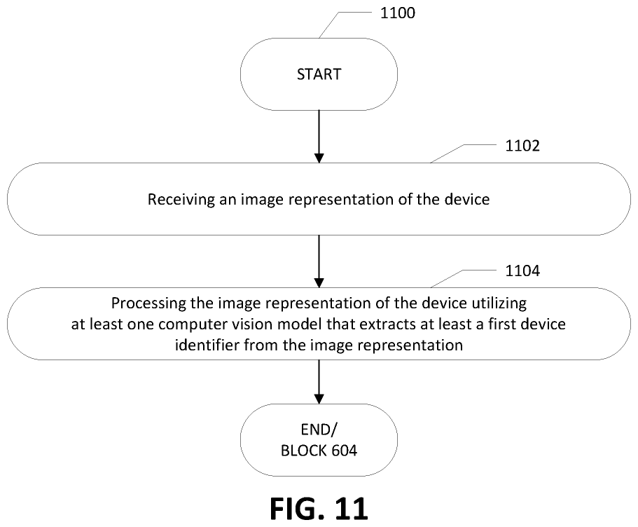

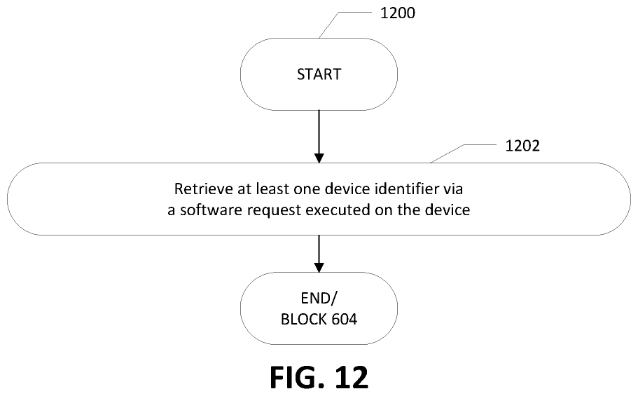

The process 600 begins at operation 602. At operation 602, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that receives at least one device identifier associated with a device. In some embodiments, one or more of the at least one device identifier is received via user input, for example from an end user device or an end user terminal. For example, a user may utilize their smartphone or a public user terminal (e.g., at a carrier location) to input at least one device identifier. In some embodiments, the at least one device identifier includes a serial number associated with the device to be processed and an IMEI associated with the device to be processed. Additionally or alternatively, in some embodiments, the apparatus 200 identifies one or more of the at least one device identifier via one or more software request(s) executed via the device. Additionally or alternatively, in some embodiments, the apparatus 200 identifies one or more of the at least one device identifier via another computer-implemented process, for example utilizing image processing, computer vision, and/or the like. Non-limiting examples of computer-implemented processes for receiving at least one device identifier associated with a device are described herein with respect to FIGS. 11 and 12 herein.

At operation 604, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that applies the at least one device identifier to an expected device attribute model. In some embodiments, the expected device attribute model determines at least one expected device attribute associated with the device. For example, in some embodiments, the expected device attribute model is specially trained based at least in part on a training data set to determine the at least one expected device attribute representing predicted expected device attribute(s) based at least in part on the at least one device identifier inputted to the model for processing. The trained expected device attribute model may determine such expected device attribute(s) based at least in part on pattern(s), trend(s), and/or other data determinations derived from each device identifier and/or combination of device identifiers.

In some embodiments, the apparatus 200 processes the at least one device identifier for processing by the expected device attribute model. For example, in some embodiments, the apparatus 200 processes each device identifier of the at least one device identifier to parse various portions of the parsed device identifier. For example, in some embodiments, the apparatus 200 utilizes a determined delimiter to parse particular sub-portions from a particular device identifier. For example, in some embodiments, a predetermined character is identified as delimiter that separates different portions corresponding to different features within a particular device identifier. In some embodiments the different portions of a device identifier and/or the delimiter(s) separating such portion(s) is/are identified by processing a data set of the same type of device identifiers associated with known device attributes, for example via a machine learning model, neural network, algorithm, and/or the like. Alternatively or additionally, in some embodiments, the apparatus 200 parses a particular device identifier based at least in part on a predetermined format associated with the device identifier. In some embodiments, the apparatus 200 parses the device identifier into particular sections that define different data values for different device attributes.

The parsed portions of the device identifier may represent any number of data values for features utilized for processing the device identifier via one or more machine learning model(s), for example a specially trained expected device attribute model. The parsed portions of the device identifier in some such embodiments represent a feature vector for processing by such model(s). In some embodiments the apparatus 200 performs labeling encoding of one or more different data values parsed from different portions of a device identifier. For example, in some embodiments, the label encoding converts different label values into corresponding machine-readable formats for purposes of use with one or more machine learning model(s). In some embodiments, the label encoding is performed within a particular feature and/or embedding space. In some embodiments, the feature vector updated with the encoded labels is processable by the one or more model(s), for example the expected device attributes model.

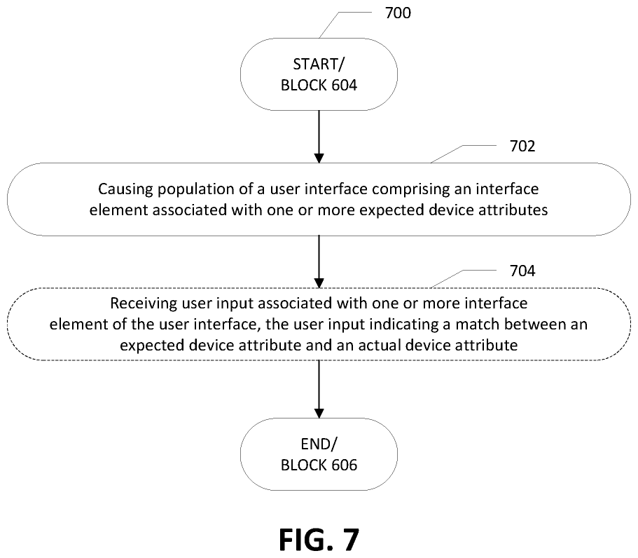

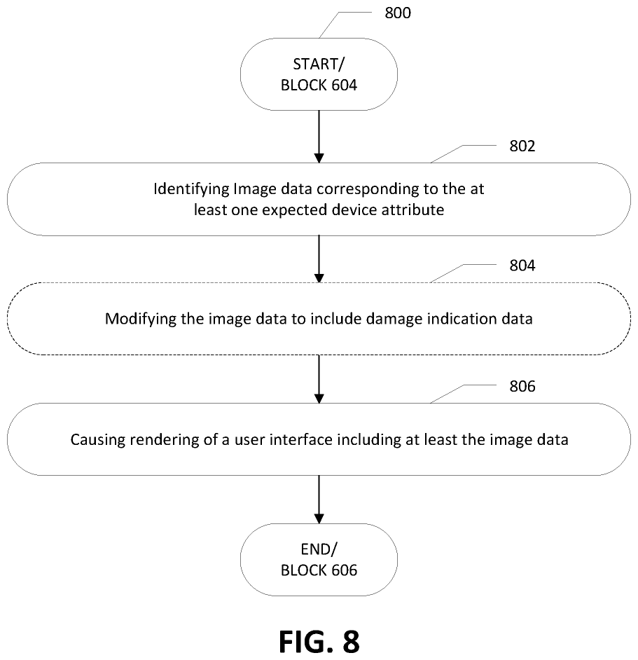

At operation 606, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that outputs at least the at least one expected device attribute. In some embodiments, the at least one expected device attribute represents values for particular characteristic(s) of a device modeled from a feature vector inputted to the expected device attributes model. In some embodiments, the apparatus 200 outputs the at least one expected device attribute via at least one data transmission for further processing. Additionally or alternatively, in some embodiments, the apparatus 200 outputs the at least one expected device attribute via at least one data transmission over a communications network to an end user device for processing and/or display. For example, in some embodiments, at least the at least one device identifier is outputted in a manner that is utilized to cause rendering of one or more particular user interface element(s) based at least in part on such at least one device attribute. Non-limiting examples of outputting at least the at least one expected device attribute is described herein with respect to FIGS. 7, 8, and/or 9.

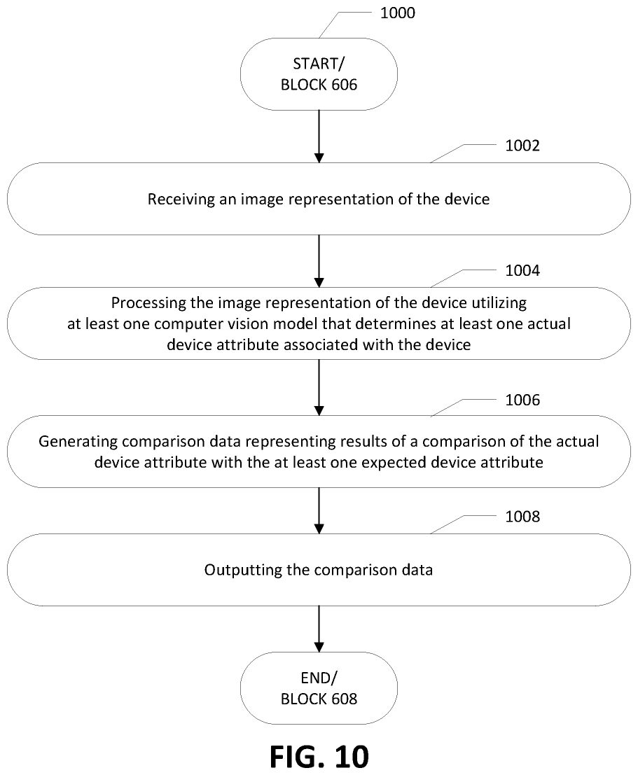

At optional operation 608, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that initiates a computer-implemented process based at least in part on the at least one expected device attribute. For example, in some embodiments, the at least one expected device attribute is/are utilized as trigger(s) for a particular computer-implemented process. In some embodiments, the apparatus 200 initiates a first computer-implemented method in a circumstance where the at least one expected device attribute represents a first value for a device characteristic, and initiates a second computer-implemented process in a circumstance where the at least one expected device attribute represents a second value for the device characteristic. Alternatively or additionally, in some embodiments, the apparatus 200 initiates one or more computer-implemented process(es) for validating whether the expected device attribute(s) match actual device attribute(s) for a particular device. Non-limiting examples of initiating a computer-implemented process based at least in part on the at least one expected device attribute is described herein with respect to FIG. 10.

At optional operation 610, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that receives feedback attribute data. In some embodiments, the feedback attribute data is received from at least one end user device, for example to which the at least one expected device attribute was output. In some embodiments, the feedback attribute data is associated with at least a particular expected device attribute of the at least one expected device attribute. For example, in some embodiments, the feedback attribute data indicates results of a user determination of whether one or more of the at least one expected device attribute(s) match one or more actual device attribute(s) for the device.

At optional operation 612, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that updates training of the expected device attribute model based at least in part on the feedback attribute data. For example, in some embodiments, the feedback attribute data is utilized to create a new record in a training data set utilized to further train the expected device attribute model. It will be appreciated that the expected device attribute model may be trained in stage(s) and/or immediately upon receiving and/or processing of the feedback attribute data by the apparatus 200.

FIG. 7 illustrates a flowchart depicting example operations of a process for outputting expected device attribute(s) via a populated user interface, for example as part of a process for modeling expected device attributes, in accordance with at least some example embodiments of the present disclosure. Specifically, FIG. 7 depicts an example process 700. In some embodiments, the process 700 is embodied by computer program code stored on a non-transitory computer-readable storage medium of a computer program product configured for execution to perform the process as depicted and described. Alternatively or additionally, in some embodiments, the process 700 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data, and/or the like. For purposes of simplifying the description, the process 700 is described as performed by and from the perspective of the apparatus 200.

The process 700 begins at operation 702. In some embodiments, the process 700 begins after one or more operations depicted and/or described with respect to any one of the other processes described herein, for example after operation 604 of the process 600. In this regard, some or all of the process 700 may replace or supplement one or more blocks depicted and/or described with respect to any of the processes described herein. Upon completion of the process 700, the flow of operations may terminate. Additionally or alternatively, as depicted, upon completion of the process 700 in some embodiments, flow may return to one or more operation(s) of another process, such as the operation 606. It will be appreciated that, in some embodiments, the process 700 embodies a sub-process of one or more other process(es) depicted and/or described herein, for example the process 600.

At operation 702, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that causes population of a user interface based at least in part on the at least one expected device attribute. For example, in some embodiments the user interface includes an interface element associated with one or more device attributes. In some embodiments the user interface includes an interface element associated with each expected device attribute. In some embodiments, the user interface embodies a checklist including a representation of each expected device attribute for visualization at a display, for example a display of the apparatus 200 and/or an end user device communicable with the apparatus 200. Additionally or alternatively, in some embodiments, the user interface is populated with a user interface element corresponding to each of the at least one expected device attributes, where each user interface element is engageable for a user to indicate whether an actual device attribute matches or does not match a corresponding expected device attribute for a particular device characteristic. In this regard, the apparatus 200 may automatically populate such a checklist for use by a particular end user in confirming matches with the actual device attributes, for example via visual manual confirmation.

At optional operation 704, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that receive user input associated with one or more interface elements of the user interface. For example, in some embodiments, the user input indicates a match between an expected device attribute and an actual device attribute. For example, the user interface may embody a checklist of each expected device attribute, which enables a user to submit user input corresponding to a particular interface element to indicate that an expected device attribute matches a corresponding actual device attribute. The user may indicate whether any of the expected device attribute(s) does not match a corresponding actual device attribute accordingly.

FIG. 8 illustrates a flowchart depicting example operations of a process for outputting expected device attribute(s) via at least one image, for example as part of a process for modeling expected device attributes, in accordance with at least some example embodiments of the present disclosure. Specifically, FIG. 8 depicts an example process 800. In some embodiments, the process 800 is embodied by computer program code stored on a non-transitory computer-readable storage medium of a computer program product configured for execution to perform the process as depicted and described. Alternatively or additionally, in some embodiments, the process 800 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data system, and/or the like. For purposes of simplifying the description, the process 800 is described as performed by and from the perspective of the apparatus 200.

The process 800 begins at operation 802. In some embodiments, the process 800 begins after one or more operations depicted and/or described with respect to any one of the other processes described herein, for example after operation 604 of the process 600. In this regard, some or all of the process 800 may replace or supplement one or more blocks depicted and/or described with respect to any of the processes described herein. Upon completion of the process 800, the flow of operations may terminate. Additionally or alternatively, as depicted, upon completion of the process 800 in some embodiments, flow may return to one or more operation(s) of another process, such as the operation 606. It will be appreciated that, in some embodiments, the process 800 embodies a sub-process of one or more other process(es) depicted and/or described herein, for example the process 600.

At operation 802, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that identifies image data corresponding to the at least one expected device attribute. For example, in some embodiments, the at least one expected device attribute includes at least one value representing a device make and device model utilized to retrieve particular image data depicting that device. Additionally or alternatively, in some embodiments, such data is combined with an expected device attribute representing a color of the device having the particular make and/or model. Additionally or alternatively still, in some embodiments, the image data depicts a particular device of a particular make and model having a particular physical condition, color, and/or the like, as represented by the at least one expected device attribute. In some embodiments, the apparatus utilizes the values of the at least one expected device attribute as a key to retrieve the image data from at least one database. It will be appreciated that the at least one database may be embodied utilizing any of a myriad of data structure(s) that enables retrieval of a plurality or all permutations of candidate device attributes.

At operation 802, the apparatus 200 may optionally include identifier retrieval circuitry 210, attribute modeling circuitry 212, attribute processing circuitry 214, model management circuitry 216, communications circuitry 208, input/output circuitry 206, processor 202, and/or the like, or a combination thereof, that modifies the image data to include damage indication data. In some embodiments, the apparatus may also receive damage indication data indicative of damage that has occurred to the device, such as, for example, during a trade-in, warranty claim, or similar process. In such instances, the apparatus may be configured to modify the image data (though not necessarily requiring two separate images to be created) to show the damage associated with the device. For example, in an instance in which the damage indication data indicates that a screen of the device is cracked, the apparatus may modify the image data corresponding to the at least one expected device attribute to illustrate example damage on the device shown in the image data.

At operation 806, the apparatus 200 includes identifier retrieval circuitry 210, attribute modeling circuitry 212, attribute processing circuitry 214, model management circuitry a combination thereof, that causes rendering of a user interface including at least the image data. In some embodiments, the apparatus 200 renders the user interface to a display of the apparatus 200. Alternatively or additionally, in some embodiments, the apparatus 200 transmits at least the image data to at least one user device to cause rendering of the user interface including the image data via a display of the user device. In this regard, the user interface including at least the image data may be referenced by a user to determine what the corresponding actual device having the expected device attribute(s) is expected to look.

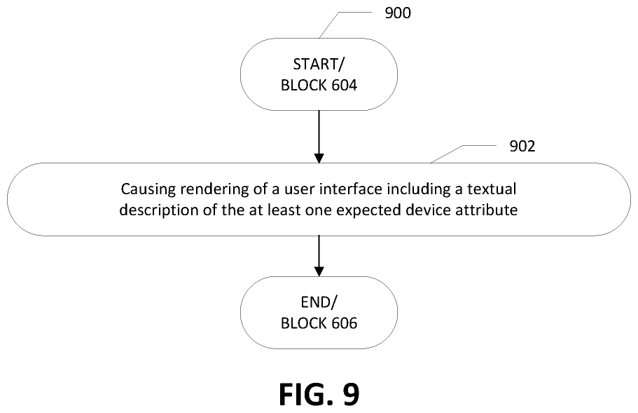

FIG. 9 illustrates a flowchart depicting example operations of a process for outputting expected device attribute(s) via at least one textual description, for example as part of a process for modeling expected device attributes, in accordance with at least some example embodiments of the present disclosure. Specifically, FIG. 9 depicts an example process 900. In some embodiments, the process 900 is embodied by computer program code stored on a non-transitory computer-readable storage medium of a computer program product configured for execution to perform the process as depicted and described. Alternatively or additionally, in some embodiments, the process 900 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data system, and/or the like. For purposes of simplifying the description, the process 900 is described as performed by and from the perspective of the apparatus 200.

The process 900 begins at operation 902. In some embodiments, the process 900 begins after one or more operations depicted and/or described with respect to any one of the other processes described herein, for example after operation 604 of the process 600. In this regard, some or all of the process 900 may replace or supplement one or more blocks depicted and/or described with respect to any of the processes described herein. Upon completion of the process 900, the flow of operations may terminate. Additionally or alternatively, as depicted, upon completion of the process 900 in some embodiments, flow may return to one or more operation(s) of another process, such as the operation 606. It will be appreciated that, in some embodiments, the process 900 embodies a sub-process of one or more other process(es) depicted and/or described herein, for example the process 600.

At operation 902, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that causes rendering of a user interface including a textual description of the at least one expected device attribute. In some embodiments, the user interface includes a textual description for each expected device attribute of the at least one expected device attribute. The textual description in some embodiments includes a human-interpretable description of the expected device attribute. In one non-limiting example context, a textual description corresponding to an expected device attribute indicating a device color of red may be rendered to the user interface as “The device color is: red.” or the like. In some embodiments, the apparatus 200 causes rendering of the user interface to a display of the apparatus 200. Alternatively or additionally, in some embodiments, the apparatus 200 causes rendering of the user interface to a display of an associated user device, for example by transmitting at least one data transmission including or representing the at least one expected device attribute to the user device for rendering.

FIG. 10 illustrates a flowchart depicting example operations of a process for determining whether actual device attribute(s) match expected device attribute(s), for example as part of a process for modeling expected device attributes, in accordance with at least some example embodiments of the present disclosure. Specifically, FIG. 10 depicts an example process 1000. In some embodiments, the process 1000 is embodied by computer program code stored on a non-transitory computer-readable storage medium of a computer program product configured for execution to perform the process as depicted and described. Alternatively or additionally, in some embodiments, the process 1000 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data system, and/or the like. For purposes of simplifying the description, the process 1000 is described as performed by and from the perspective of the apparatus 200.

The process 1000 begins at operation 1002. In some embodiments, the process 1000 begins after one or more operations depicted and/or described with respect to any one of the other processes described herein, for example after operation 606 of the process 600. In this regard, some or all of the process 1000 may replace or supplement one or more blocks depicted and/or described with respect to any of the processes described herein. Upon completion of the process 1000, the flow of operations may terminate. Additionally or alternatively, as depicted, upon completion of the process 1000 in some embodiments, flow may return to one or more operation(s) of another process, such as the optional operation 608. It will be appreciated that, in some embodiments, the process 1000 embodies a sub-process of one or more other process(es) depicted and/or described herein, for example the process 600.

At operation 1002, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that receives an image representation of a device. In some embodiments, the image representation embodies image data captured via one or more camera(s) of the apparatus 200. Alternatively or additionally, in some embodiments, the image representation is transmitted to the apparatus 200 from an external device, such as an end user device, that captures the image representation. The image representation of the device may represent a captured image of the device for which one or more device identifier(s) were identified and/or processed, for example as described with respect to the process 600 herein.

At operation 1004, the apparatus 200 includes identifier retrieval circuitry 210, attribute modeling circuitry 212, attribute processing circuitry 214, model management circuitry a combination thereof, that processes the image representation of the device utilizing at least one computer vision model. In some embodiments, the computer vision model determines at least one actual device attribute associated with the device. For example, in some embodiments, the computer vision model processes the image representation to determine a make, model, color, physical condition, and/or other physical characteristics of a device depicted in the image representation. In some such embodiments, the computer vision model may perform object detection to detect the device from the image representation.

At operation 1006, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that generates comparison data representing results of a comparison of the actual device attribute with the at least one expected device attribute. In some embodiments, the apparatus 200 compares each actual device attribute with a corresponding expected device attribute of the at least one expected device attribute determined via at least one expected attribute model. In some embodiments, each comparison generates comparison data that indicates whether the actual device attribute matches the corresponding expected device attribute. For example, the apparatus 200 may generate a first value to indicate a match between the actual device attribute and a corresponding expected device attribute of the at least one expected device attribute, and a second value to indicate no match between the actual device attribute and the corresponding expected device attribute.

At operation 1008, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that outputs the comparison data. In some embodiments, the apparatus 200 outputs the comparison data via at least one user interface. In some such embodiments, the apparatus 200 causes rendering of a user interface including at least the comparison data to a display of the apparatus 200. Alternatively or additionally, in some embodiments, the apparatus 200 causes rendering of the user interface including at least the comparison data to a display of a user device, for example by transmitting one or more transmission(s) to the user device to cause the rendering.

FIG. 11 illustrates a flowchart depicting example operations of a process for receiving device identifier(s) via image processing, for example as part of a process for modeling expected device attributes, in accordance with at least some example embodiments of the present disclosure. Specifically, FIG. 11 depicts an example process 1100. In some embodiments, the process 1100 is embodied by computer program code stored on a non-transitory computer-readable storage medium of a computer program product configured for execution to perform the process as depicted and described. Alternatively or additionally, in some embodiments, the process 1100 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data system, and/or the like. For purposes of simplifying the description, the process 1100 is described as performed by and from the perspective of the apparatus 200.

The process 1100 begins at operation 1102. In some embodiments, the process 1100 begins after one or more operations depicted and/or described with respect to any one of the other processes described herein. In this regard, some or all of the process 1100 may replace or supplement one or more blocks depicted and/or described with respect to any of the processes described herein. Upon completion of the process 1100, the flow of operations may terminate. Additionally or alternatively, as depicted, upon completion of the process 1100 in some embodiments, flow may return to one or more operation(s) of another process, such as the optional operation 604. It will be appreciated that, in some embodiments, the process 1100 embodies a sub-process of one or more other process(es) depicted and/or described herein, for example the process 600.

At operation 1102, the apparatus 200 includes identifier retrieval circuitry 210, attribute modeling circuitry 212, attribute processing circuitry 214, model management circuitry a combination thereof, that receives an image representation of the device. In some embodiments, the image representation is captured by the apparatus 200. For example, the apparatus 200 may capture the image representation utilizing one or more camera(s) of the apparatus 200. Additionally or alternatively, in some embodiments, the apparatus 200 receives the image representation from an external device. For example, in some embodiments, the apparatus 200 receives the image representation from a user device. In some embodiments, the image representation of the device includes a photographic representation of the device to be processed.

At operation 1104, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that processes the image representation of the device utilizing at least one computer vision model. In some embodiments, the at least one computer vision model extracts at least a first device identifier from the image representation. The first device identifier may embody a device identifier physically labeled or printed on an external portion of the device. For example, in some embodiments, the computer vision model performs object detection to identify data visually representing the device in the image representation, and/or extracts particular data on such image representation of the device (e.g., text labeled on the device). In some such embodiments, the first device identifier extracted from the image representation may be utilized as one of at least one device identifier processed by the apparatus 200, for example for use in modeling expected device attribute(s) using at least one expected device attribute model as described with respect to the process 600.

FIG. 12 illustrates a flowchart depicting example operations of a process for receiving device identifier(s) via software request(s), for example as part of a process for modeling expected device attributes, in accordance with at least some example embodiments of the present disclosure. Specifically, FIG. 12 depicts an example process 1200. In some embodiments, the process 1200 is embodied by computer program code stored on a non-transitory computer-readable storage medium of a computer program product configured for execution to perform the process as depicted and described. Alternatively or additionally, in some embodiments, the process 1200 is performed by one or more specially configured computing devices, such as the apparatus 200 alone or in communication with one or more other component(s), device(s), system(s), and/or the like. In this regard, in some such embodiments, the apparatus 200 is specially configured by computer-coded instructions (e.g., computer program instructions) stored thereon, for example in the memory 204 and/or another component depicted and/or described herein and/or otherwise accessible to the apparatus 200, for performing the operations as depicted and described. In some embodiments, the apparatus 200 is in communication with one or more external apparatus(es), system(s), device(s), and/or the like, to perform one or more of the operations as depicted and described. For example, the apparatus 200 in some embodiments is in communication with a separate end user device, third-party data system, and/or the like. For purposes of simplifying the description, the process 1200 is described as performed by and from the perspective of the apparatus 200.

The process 1200 begins at operation 1202. In some embodiments, the process 1200 begins after one or more operations depicted and/or described with respect to any one of the other processes described herein. In this regard, some or all of the process 1200 may replace or supplement one or more blocks depicted and/or described with respect to any of the processes described herein. Upon completion of the process 1200, the flow of operations may terminate. Additionally or alternatively, as depicted, upon completion of the process 1200 in some embodiments, flow may return to one or more operation(s) of another process, such as the optional operation 604. It will be appreciated that, in some embodiments, the process 1200 embodies a sub-process of one or more other process(es) depicted and/or described herein, for example the process 600.

At operation 1202, the apparatus 200 includes identifier retrieval circuitry 210, attribute modeling circuitry 212, attribute processing circuitry 214, model management circuitry 216, communications circuitry 208, input/output circuitry 206, processor 202, and/or the like, or a combination thereof, that retrieves at least one device identifier via a software request executed on the device. In some embodiments, the apparatus 200 transmits one or more transmission(s) to the device to initiate the software request on the device. The device may perform the software request via the operating system of the device. Alternatively or additionally, in some embodiments, the device performs the software request via one or more specially configured application executed via the device. It will be appreciated that any number of software request(s) may be executed via the device to retrieve any number of device identifier(s). The at least one device identifier retrieved via the at least one software request in some embodiments are utilized by the apparatus 200 for modeling expected device attribute(s), for example as described herein with respect to the process 600.

It will be appreciated in light of the present disclosure that the depicted processes may be performed by embodiments of the various devices disclosed herein and in various combinations with one or more other processes disclosed herein. By way of non-limiting example, the process of FIG. 6 may be used with one or more of the processes of FIGS. 7-12. By way of additional non-limiting example, the process of FIGS. 7, 8, and/or 9 may be used with one or more of the processes of FIG. 6 and/or FIGS. 10, 11, and/or 12. By way of additional non-limiting example, the process of FIGS. 10, 11, and/or 12 may be used with one or more of the processes of FIG. 6 and/or FIGS. 7, 8, and/or 9.

Moreover, the processes described herein may be performed with one or more additional processes, such as a fraud detection process that generates one or more expected attributes based on a device identifier and compares the expected attribute(s) to one or more attributes provided by a user or a third party system (e.g., a fraud check). In some embodiments, the processes described herein may be configured to facilitate the operation of one or more device-handling systems (e.g., pick systems, conveyor assemblies, robotic arms, and the like) by identifying a device and/or one or more attributes associated with a device for sorting and downstream processing (e.g., repair, refurbishment, and/or shipping).

### CONCLUSION

In some embodiments, some of the operations above may be modified or further amplified. Furthermore, in some embodiments, additional optional operations may be included. Modifications, amplifications, or additions to the operations above may be performed in any order and in any combination.

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

Although an example processing system has been described above, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

What is claimed is:

1. An apparatus for modeling expected device attributes, the apparatus comprising at least one processor and at least one non-transitory memory including computer-coded instructions thereon, the computer coded instructions, with the at least one processor, cause the apparatus to:
receive at least one device identifier associated with a device;
apply the at least one device identifier to an expected device attribute model that determines at least one expected device attribute associated with the device; and
output at least the at least one expected device attribute.

2. The apparatus of claim 1, wherein the at least one expected device attribute comprises a device manufacturer, a device model, a device operating system, a device color, a device capacity, a device country of origin, or a combination of the device manufacturer, the device model, the device operating system, the device color, the device capacity, and the device country of origin.

3. The apparatus of claim 1, wherein the at least one device identifier comprises device data that is unavailable via physically accessing an exterior of the device.

4. The apparatus of claim 1, wherein the at least one device identifier comprises a device serial number, a device international manufacturer equipment identifier, a device SKU, a device part number, or a combination of the device serial number, the device international manufacturer equipment identifier, the device SKU, and the device part number.

5. The apparatus of claim 1, wherein to apply the at least one device identifier to the expected device attribute model the apparatus is caused to at least:
determine the at least one expected device attribute comprising an expected physical condition of the device.

6. The apparatus of claim 1, wherein to output the at least at least one expected device attribute the apparatus is caused to:
cause population of a user interface comprising an interface element associated with each device attribute of the at least one expected device attribute.

7. The apparatus of claim 1, wherein to output at least the at least one expected device attribute the apparatus is caused to:
identify image data corresponding to the at least one expected device attribute; and
cause rendering of a user interface comprising at least the image data.

8. The apparatus of claim 7, further comprising modifying the image data to include damage indication data associated with the device, and wherein the image data comprises a representation of damage corresponding to the data indication data.

9. The apparatus of claim 1, wherein to output the at least at least one expected device attribute the apparatus is caused to:
cause rendering of a user interface comprising a textual description of the at least one expected device attribute.

10. The apparatus of claim 1, wherein the expected device attribute model is trained to determine a confidence value associated with each of the at least one expected device attribute.

11. The apparatus of claim 1, wherein the expected device attribute model is trained to generate a confidence value associated with each of a plurality of candidate device attributes, and wherein the apparatus determines the at least one expected device attribute based at least in part on each confidence value satisfying a confidence threshold.

12. The apparatus of claim 1, wherein the at least one expected device attribute comprises a plurality of candidate device attributes corresponding to a particular device attribute type.

13. The apparatus of claim 1, the apparatus further caused to:
receive feedback attribute data associated with at least a particular expected device attribute of the at least one expected device attribute, wherein the feedback attribute data indicates whether the particular expected device attribute accurately represented an actual device attribute of the device; and
update training of the expected device attribute model based at least in part on the feedback attribute data.

14. The apparatus of claim 1, the apparatus further caused to:
receive an image representation of the device;
process the image representation of the device utilizing at least one computer vision model that determines at least one actual device attribute associated with the device;
generate comparison data representing results of a comparison of the actual device attribute with the at least one expected device attribute; and
output the comparison data.

15. The apparatus of claim 1, wherein to receive the at least one device identifier associated with the device the apparatus is caused to:
receive an image representation of the device; and
process the image representation of the device utilizing at least one computer vision model that extracts at least a first device identifier from the image representation.

16. The apparatus of claim 1, wherein to receive the at least one device identifier associated with the device the apparatus is caused to:
retrieve the at least one identifier via a software request executed on the device.

17. The apparatus of claim 1, wherein the expected device attribute model comprises at least one specially-trained machine learning model.

18. The apparatus of claim 1, the apparatus further caused to:
initiate a computer-implemented process based at least in part on the at least one expected device attribute.

19. A computer-implemented method for modeling expected device attributes comprising:
receiving at least one device identifier associated with a device;
applying the at least one device identifier to an expected device attribute model that determines at least one expected device attribute associated with the device; and
outputting at least the at least one expected device attribute.

20. A computer program product for modeling expected device attributes, the computer program product comprising at least one non-transitory computer-readable storage medium having computer program code stored thereon that, in execution with at least one processor, configures the computer program product to:
receive at least one device identifier associated with a device;
apply the at least one device identifier to an expected device attribute model that determines at least one expected device attribute associated with the device; and
output at least the at least one expected device attribute.
